(19) United States
(12) Patent Application Publication
(10) Pub. No.: US 2013/0009165 A1
(43) Pub. Date: Jan. 10, 2013

(54) NITRIDE SEMICONDUCTOR DEVICE, METHOD FOR MANUFACTURING THE SAME AND NITRIDE SEMICONDUCTOR POWER DEVICE

(75) Inventors: Young Hwan Park, Seoul (KR); Ki Yeol Park, Gyeonggi-do (KR); Woo Chul Jeon, Gyeonggi-do (KR)

(73) Assignee: Samsung Electro-Mechanics Co., Ltd., Suwon (KR)

(21) Appl. No.: 13/470,807

(22) Filed: May 14, 2012

(30) Foreign Application Priority Data
Jul. 4, 2011 (KR) 10-2011-0065922

(51) Int. Cl. H01L 29/778; H01L 21/335; H01L 27/06

(52) U.S. Cl. 257/76; 257/195; 438/172; 257/E27.016; 257/E29.246; 257/E21.403

(57) ABSTRACT

Disclosed herein are a nitride semiconductor device, a method for manufacturing the same, and a nitride semiconductor power device. According to an exemplary embodiment of the present invention, a nitride semiconductor device includes: a nitride semiconductor layer over a substrate wherein the nitride semiconductor layer has a two-dimensional electron gas (2DEG) channel formed therein; a D-mode FET that includes a gate electrode Schottky-contacting with the nitride semiconductor layer to form a normally-on operating depletion-mode (D-mode) HEMT structure; and a Schottky diode part that includes an anode electrode Schottky-contacting with the nitride semiconductor layer and increases a gate driving voltage of the D-mode FET, the anode electrode being connected to the gate electrode of the D-mode FET. In addition, the nitride semiconductor power device and the method for manufacturing a nitride semiconductor device are proposed.

CROSS REFERENCE(S) TO RELATED APPLICATIONS

This application claims the benefit under 35 U.S.C. Section 119 of Korean Patent Application Serial No. 10-2011-0065922, entitled “Nitride Semiconductor Device, Method For Manufacturing The Same And Nitride Semiconductor Power Device” filed on Jul. 4, 2011, which is hereby incorporated by reference in its entirety into this application.

### BACKGROUND OF THE INVENTION

1. Technical Field

The present invention relates to a nitride semiconductor device, a method for manufacturing the same, and a nitride semiconductor power device. More particularly, the present invention relates to a nitride semiconductor device for effectively using integration of a GaN power device and a normally-on HEMT, a method for manufacturing the same, and a nitride semiconductor power device.

2. Description of the Related Art

A focus on saving power consumption has been increased due to a green energy policy, or the like. To this end, there is a need to increase power conversion efficiency. In the power conversion, the overall power conversion efficiency depends on an efficiency of a power switching device.

Today, as power devices generally used, a power MOSFET or an IGBT using silicon has been mainly used. However, there is a limitation in the efficiency increase in devices due to a limitation of a silicon material. To resolve the above problems, patents for increasing conversion efficiency by manufacturing a transistor using a nitride semiconductor such as gallium nitride (GaN) have been filed.

However, for example, a high electron mobility transistor (HEMT) structure using GaN is in a ‘turn-on’ state in which current flows due to low resistance between a drain electrode and a source electrode when gate voltage is 0V (normal state). Therefore, current and power are consumed. In order to turn-off the high electron mobility transistor, there is a need to apply negative voltage (for example, −5V) to a gate electrode (a normally-on structure).

In order to resolve the above problem, patents for implementing a normally-off operation using various structures have been filed. However, a general normally-off structure may degrade characteristics, such as lowering current density and pressure resistance, or the like, in a turn-on state, as compared with the normally-on structure.

To resolve the above problems, patents for implementing the normally-off by a cascode connection of a normally-on GaN HEMT and a normally-off FET have been filed.

FIG. 7 shows a nitride semiconductor power device according to the related art. FIG. 7 corresponds to a diagram disclosed in US Laid-Open Patent No. US 2008/0230784A and shows a normally-off operating device structure by using bonding and packaging the normally-on GaN HEMT and the silicon MOSFET in a single package. The normally-off operating GaN HEMT has been implemented by a cascode connection of a depletion-mode GaN HEMT and the silicon MOSFET. In order to minimize the power consumption due to the normally-on operation that causes a problem in manufacturing a high power GaN HEMT, the normally-off characteristic of the silicon MOSFET has been used. That is, the normally-on HEMT performs a normally-off operation by cascode-connected to the silicon MOSFET.

The normally-off operating device structure of FIG. 7 may use the electrical characteristics of the normally-on GaN HEMT while implementing the normally-off characteristics; however, since Vgs (gate-source voltage) of the normally-on GaN HEMT is a negative value approximating 0V when being turned-on, the normally-off operating device prevents a large amount of Ids (drain-source current) from flowing, thereby increasing the turn-on resistance and increasing the switching loss of the device.

### SUMMARY OF THE INVENTION

An object of the present invention is to integrate a GaN power device and effectively use a normally-on HEMT.

Further, another object of the present invention is to implement the normally-off (or enhanced mode) by simultaneously manufacturing the normally-on GaN HEMT and the diode on the same substrate and cascode-connecting the normally-on GaN HEMT with the normally-off FET and increase the Vgs of the normally-on GaN HEMT in the integrated type without the additional external circuits, thereby implementing high electrical characteristics and efficiency.

According to an exemplary embodiment of the present invention, there is provided a nitride semiconductor device, including: a nitride semiconductor layer over a substrate wherein the nitride semiconductor layer has a two-dimensional electron gas (2DEG) channel formed therein; a D-mode FET that includes a gate electrode Schottky-contacting with the nitride semiconductor layer to form a normally-on operating depletion-mode (D-mode) HEMT structure; and a Schottky diode part that includes an anode electrode Schottky-contacting with the nitride semiconductor layer and increases a gate driving voltage of the D-mode FET, the anode electrode being connected to the gate electrode of the D-mode FET.

The 2DEG channel may not be formed between the D-mode FET and the Schottky diode part.

A source electrode and a drain electrode of the D-mode FET may ohmic-contact with the nitride semiconductor layer.

A cathode electrode of the Schottky diode part may ohmic-contact with the nitride semiconductor layer.

The nitride semiconductor layer may include: a first nitride layer over the substrate wherein the first nitride layer includes a gallium nitride material; and a second nitride layer heterojunctioned to the first nitride layer wherein the second nitride layer includes a heterogeneous gallium nitride based material with a larger energy bandgap than the first nitride layer.

The first nitride layer may include gallium nitride (GaN) and the second nitride layer may include any one of aluminum gallium nitride (AlGaN), indium gallium nitride (InGaN), and indium aluminum gallium nitride (InAlGaN).

The second nitride layer may include a first area in which the D-mode FET is disposed and a second area in which the Schottky diode part is disposed, the first area and the second area are separated from each other, and the 2DEG channel may not be formed in the vicinity of a surface of the first nitride layer between the first area and the second area.

The D-mode FET may include: a source electrode ohmic-contacting with the first nitride layer exposed by etching the second nitride layer; a drain electrode ohmic-contacting with the first nitride layer exposed by etching the second nitride layer; and a gate electrode Schottky-contacting with the second nitride layer between the source electrode and the drain electrode, wherein a dielectric layer insulating between the Schottky diode part and the source and drain electrodes may be provided.

The source electrode and the drain electrode may each be ohmic-contacted over each portion of the first nitride layer and the second nitride layer.

The nitride semiconductor device may further include: an E-mode FET that includes electrodes formed on the nitride semiconductor layer to a normally-off form operating enhancement-mode (E-mode) HEMT structure and has a drain electrode connected to the source electrode of the D-mode FET so as to be cascode-connected to the D-mode FET.

The Schottky diode part may be formed so that two Schottky diodes are connected to each other in series.

According to another exemplary embodiment of the present invention, there is provided a nitride semiconductor power device, including: a D-mode FET that includes electrodes formed on a nitride semiconductor layer forming a 2-dimensional electron gas (2DEG) channel to form a normally-on operating depletion mode (D-mode) HEMT structure; an E-mode FET that forms a normally-off operating enhancement-mode (E-mode) HEMT structure and has a source electrode connected to a ground and a drain electrode connected to a source electrode of the D-mode FET so as to be cascode-connected to the D-mode FET; and a Schottky diode part that includes an anode electrode Schottky-contacting with the nitride semiconductor layer and a cathode electrode connected to the ground and increases a gate driving voltage of the D-mode FET, the anode electrode being connected to a gate electrode of the D-mode FET.

The Schottky diode part may be formed so that two Schottky diodes are connected to each other in series.

According to another exemplary embodiment of the present invention, there is provided a method for manufacturing a nitride semiconductor device, including: forming a nitride semiconductor layer over a substrate wherein the nitride semiconductor layer has a two-dimensional electron gas (2DEG) channel formed therein; forming a normally-on operating D-mode FET structure by forming source and drain electrodes ohmic-contacting with the nitride semiconductor layer and a gate electrode Schottky-contacting with the nitride semiconductor layer; forming a Schottky diode structure that includes a cathode electrode ohmic-contacting with the nitride semiconductor layer and an anode electrode Schottky-contacting with the nitride semiconductor layer, the Schottky diode structure being separated from the D-mode FET structure; and connecting the gate electrode of the D-mode FET to the anode electrode of the Schottky diode part so that a gate driving voltage of the D-mode FET is increased by the Schottky diode.

The forming of the nitride semiconductor layer may include: forming a first nitride layer over the substrate by epitaxial growth process, wherein the first nitride layer includes a gallium nitride based material; and forming a second nitride layer by epitaxial growth process using the first nitride layer as a seed layer, wherein the second nitride layer includes a heterogeneous gallium nitride based material having a larger energy bandgap than the first nitride layer.

The method for manufacturing a nitride semiconductor device may further include: exposing the first nitride layer by etching a portion of the second nitride layer, so that the second nitride layer is separated into the first area and the second area, wherein at the forming of the D-mode FET structure, the source electrode and the drain electrode may be formed on the exposed first nitride layer while being ohmic-contacted thereto, the gate electrode may be formed on the first area between the source electrode and the drain electrode while being Schottky-contacted thereto, at the forming of the Schottky diode structure, the cathode and anode electrodes may be formed on the second area, a dielectric layer may be formed between the Schottky diode structure and the source and drain electrodes, on the second area between the cathode electrode and the anode electrode, and over the gate electrode and the first area between the source electrode and the drain electrode, and after the dielectric layer is formed, the gate electrode of the D-mode FET may be connected to the anode electrode of the Schottky diode.

The source electrode and the drain electrode may each be formed so as to be ohmic-contacted over each portion of the first nitride layer and the first area.

The method for manufacturing a nitride semiconductor device may further include: forming the source electrode, the drain electrode, and the gate electrode on the nitride semiconductor layer to form the normally-off operating E-mode FET structure; and connecting the drain electrode of the E-mode FET to the source electrode of the D-mode FET to cascode-connect the E-mode FET to the D-mode FET.

At the forming of the Schottky diode structure, two Schottky diodes may be formed so as to be connected to each other in series.

Although not specifically stated as an aspect of the present invention, exemplary embodiments of the present invention according to possible various combinations of above-mentioned technical characteristics may be supported by the following specific exemplary embodiments and may be obviously implemented by those skilled in the art.

### BRIEF DESCRIPTION OF THE DRAWINGS

FIG. 1 is a schematic cross-sectional view of a nitride semiconductor device according to an exemplary embodiment of the present invention.

FIG. 2 is a plan view schematically showing the nitride semiconductor device shown in FIG. 1.

FIG. 3 is a schematic circuit diagram of a nitride semiconductor device according to an exemplary embodiment of the present invention.

FIG. 4 is a schematic circuit diagram of a nitride semiconductor device according to another exemplary embodiment of the present invention.

FIG. 5 is a schematic circuit diagram of a nitride semiconductor device according to another exemplary embodiment of the present invention.

FIGS. 6A-6D are diagrams schematically showing a method for manufacturing a nitride semiconductor device according to an exemplary embodiment of the present invention.

FIG. 7 is a diagram showing a nitride semiconductor power device according to the related art.

### DESCRIPTION OF THE PREFERRED EMBODIMENTS

Exemplary embodiments of the present invention for accomplishing the above-mentioned objects will be described with reference to the accompanying drawings. In describing exemplary embodiments of the present invention, the same reference numerals will be used to describe the same components and an additional description that is overlapped or allow the meaning of the present invention to be restrictively interpreted will be omitted.

It will be understood that when an element is simply referred to as being ‘connected to’ or ‘coupled to’ another element without being ‘directly connected to’ or ‘directly coupled to’ another element in the present description, it may be ‘directly connected to’ or ‘directly coupled to’ another element or be connected to or coupled to another element, having the other element intervening therebetween. In addition, in the specification, spatially relative terms, ‘on’, ‘above’, ‘upper’, ‘below’, ‘lower’, or the like, they should be interpreted as being in a ‘direct-contact’ shape or a shape in which other elements may be interposed therebetween, without a description that an element is in a ‘direct-contact’ with an object to be a basis. Furthermore, the spatially relative terms, ‘on’, ‘above’, ‘upper’, ‘below’, ‘lower’, or the like, may be used for describing a relationship of an element for another element. In this case, when a direction of the element to be a basis is reversed or changed, the spatially relative terms may include concept for directions of relative terms corresponding thereto.

Although a singular form is used in the present description, it may include a plural form as long as it is opposite to the concept of the present invention and is not contradictory in view of interpretation or is used as clearly different meaning.

It should be understood that “include”, “have”, “comprise”, “be configured to include”, and the like, used in the present description do not exclude presence or addition of one or more other characteristic, component, or a combination thereof.

In addition, the drawings referred to in the specification are ideal views for explaining embodiments of the present invention. In the drawings, the sizes, the thicknesses, or the like of films, layers, regions or the like may be exaggerated for clarity. Furthermore, the shapes of the illustrated regions in the drawings are for illustrating specific shapes and are not for limiting the scope of the present invention.

Hereinafter, a nitride semiconductor device, a power device, and a method for manufacturing the same according to exemplary embodiments of the present invention will be described in detail with reference to the accompanying drawings.

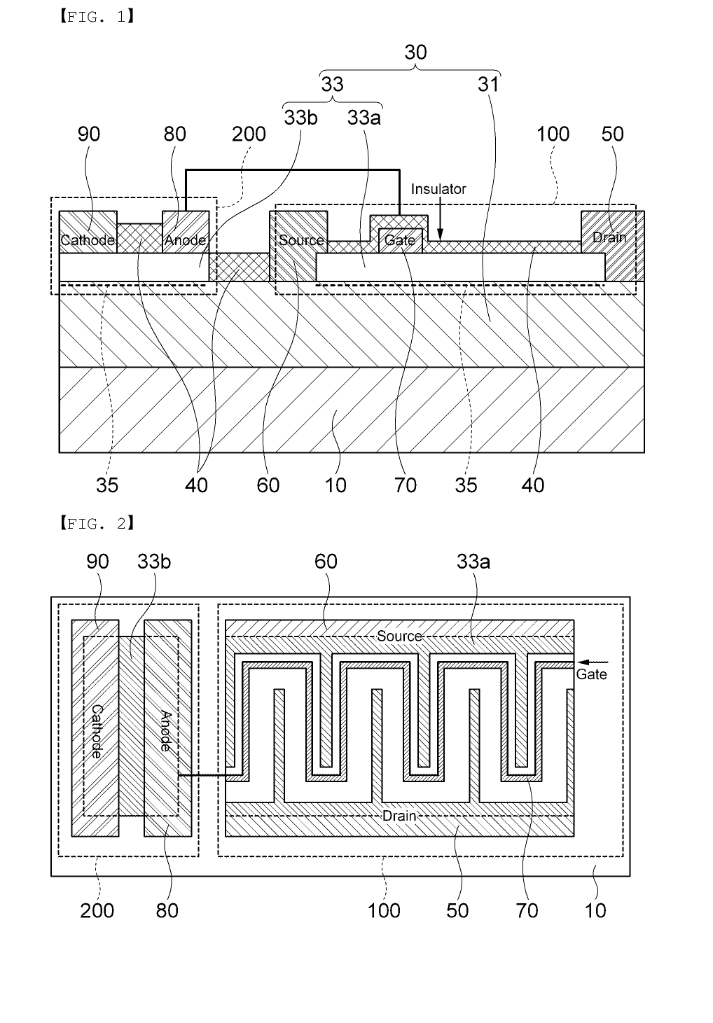

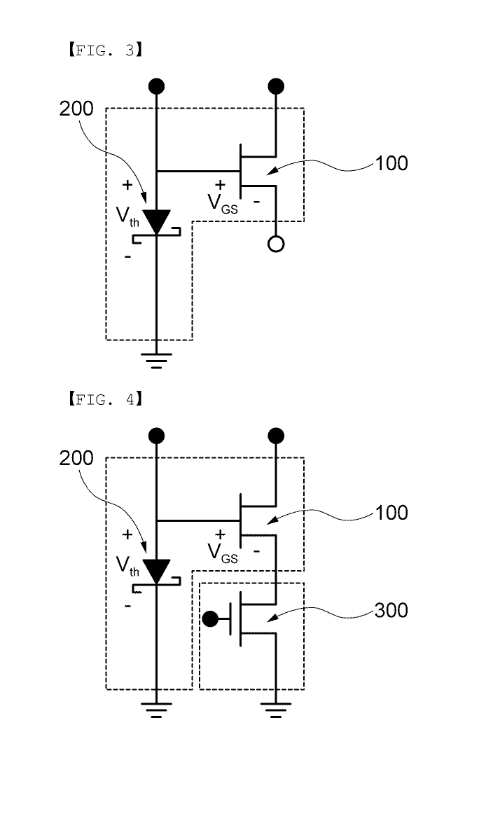

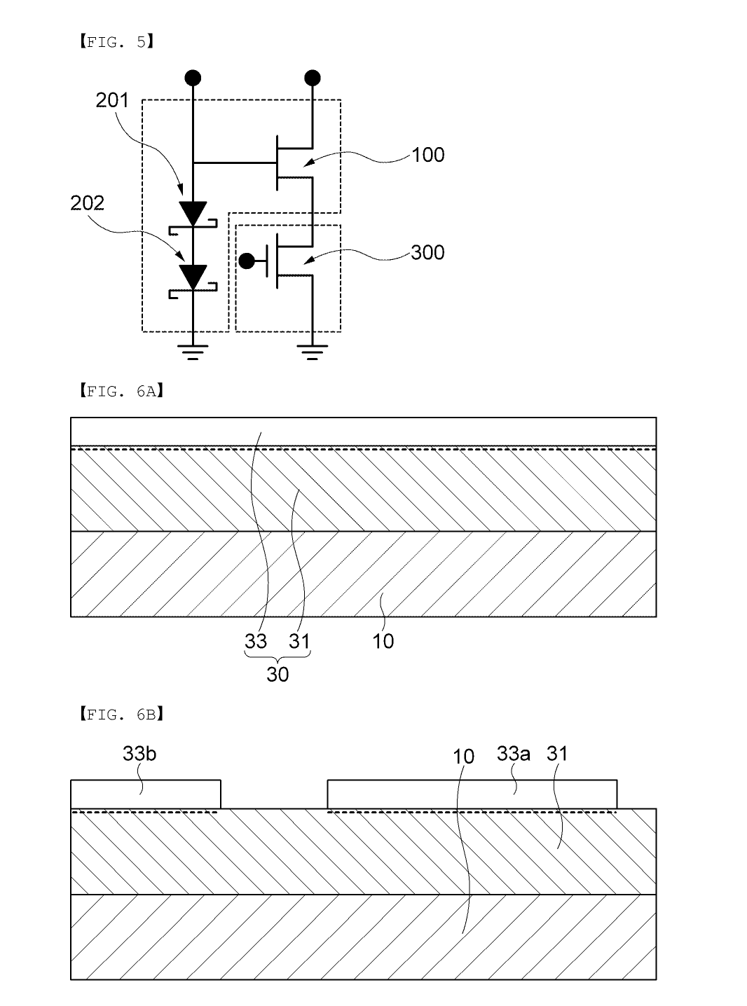

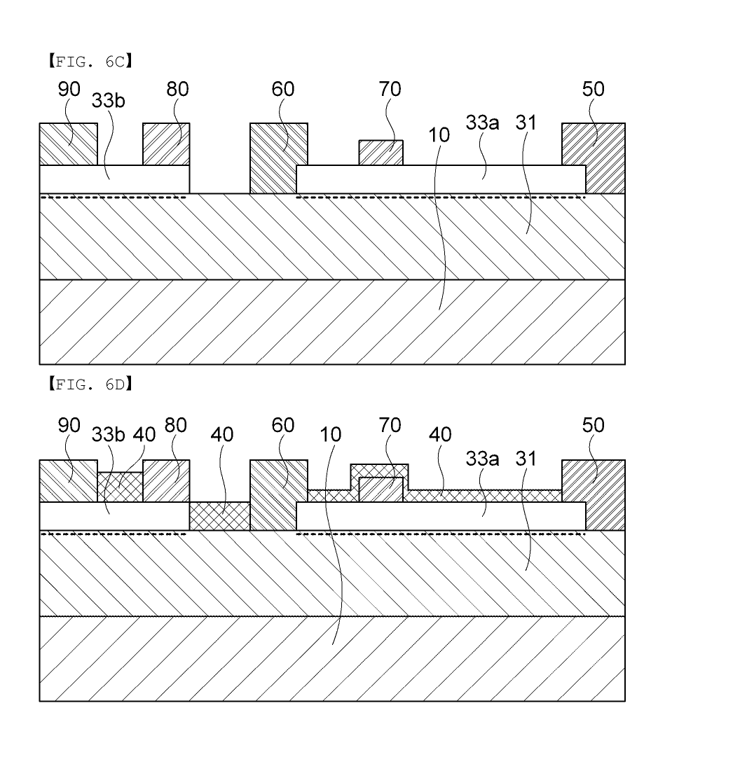

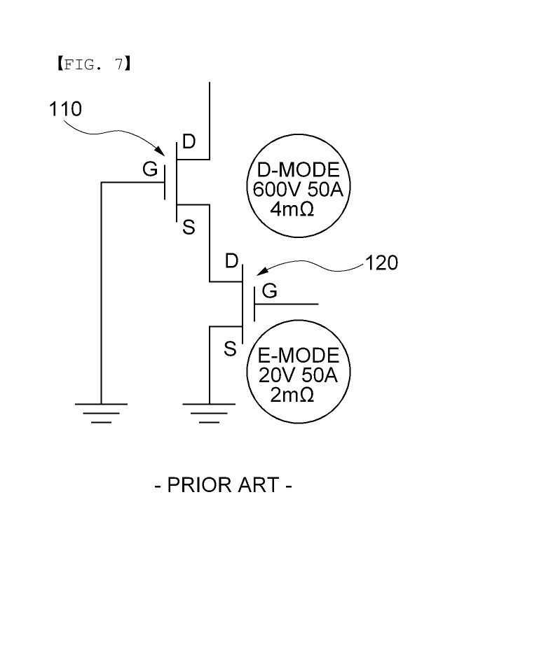

FIG. 1 is a schematic cross-sectional view of a nitride semiconductor device according to an exemplary embodiment of the present invention. FIG. 2 is a plan view schematically showing the nitride semiconductor device shown in FIG. 1. FIG. 3 is a schematic circuit diagram of the nitride semiconductor device according an exemplary embodiment of the present invention. FIG. 4 is a schematic circuit diagram of a nitride semiconductor device according to another exemplary embodiment of the present invention. FIG. 5 is a schematic circuit diagram of a nitride semiconductor device according to another exemplary embodiment of the present invention. FIGS. 6A-6D are diagrams schematically showing a method for manufacturing a nitride semiconductor device according to an exemplary embodiment of the present invention.

First, a nitride semiconductor device according to the exemplary embodiment of the present invention will be described in detail with reference to FIGS. 1 to 5.

Referring to FIGS. 1 and 3, the nitride semiconductor device is configured to include a nitride semiconductor layer 30, a D-mode FET 100, and a Schottky diode part 200.

The nitride semiconductor layer 30 is disposed on a substrate 10 and has a 2-dimensional electron gas (2DEG) channel 35 disposed therein.

The D-mode FET 100 includes a gate electrode 70 Schottky-contacting with the nitride semiconductor layer 30 to form a normally-on operating depletion-mode (D-mode) HEMT structure.

The Schottky diode part 200 includes an anode electrode 80 Schottky-contacting with the same nitride semiconductor layer 30, wherein the anode electrode 80 is connected to a gate electrode 70 of the D-mode FET.

The diode may use a constant voltage supply diode using silicon, or the like and may also configure a constant voltage supply circuit or a switching signal supply circuit.

In the exemplary embodiment of the present invention, a gate driving voltage of the D-mode FET 100 is increased by Vth of the Schottky diode 200.

In FIG. 7 of the related art, when the D-mode HEMT is turned-on, Vgs is a negative value approximating 0. On the other hand, according to the exemplary embodiment of the present invention, a potential of the gate electrode 70 of the D-mode FET 100 is increased by Vth of the Schottky diode 200 maintained at a predetermined voltage by inserting the Schottky diode 200 between the gate electrode 70 of the D-mode FET 100 and a ground, thereby increasing the Vgs value. When the Vgs value is increased, a current amount flowing through the D-mode HEMT is increased and thus, a turn-on resistance is reduced. In order to further increase the Vgs, the Schottky diode part may be further provided.

The nitride semiconductor device used for the exemplary embodiment of the present invention may be configured by a combination of a high current, high pressure resistance type D-mode FET and a constant voltage supply Schottky diode and may be configured to further include a high current, low pressure resistance E-mode FET. In this configuration, the integration implementing the devices on the same substrate may be achieved.

The exemplary embodiment of the present invention will be described in more detail.

Referring to FIG. 1, the nitride semiconductor layer 30 is disposed on a top of the substrate 10. The substrate 10 generally uses an insulating substrate and may use a high resistive substrate substantially having insulation. In one example, the substrate 10 may be manufactured using at least any one of silicon (Si), silicon carbide (SiC), and sapphire (Al₂O₃). Alternatively, the substrate 10 may be manufactured using other well-known substrate materials.

The nitride semiconductor layer 30 may be directly disposed on the top of the substrate 10. The nitride semiconductor layer 30 may be formed by epitaxially growing a nitride single crystal thin film. An example of the epitaxial growth process for forming the nitride semiconductor layer 30 may include liquid phase epitaxy (LPE), chemical vapor deposition (CVD), molecular beam epitaxy (MBE), metalorganic CVD (MOCVD), or the like.

In addition, although not shown, according to the exemplary embodiment of the present invention, a buffer layer may be provided between the substrate 10 and the nitride semiconductor layer 30 and the nitride semiconductor layer 30 may be disposed on the buffer layer. The buffer layer (not shown) is provided to solve problems due to a lattice mismatch between the substrate 10 and the nitride semiconductor layer 30. The buffer layer may be configured of a single layer and several layers including gallium nitride (GaN), aluminum gallium nitride (AlGaN), aluminum nitride (AlN), indium nitride gallium (InGaN), indium aluminum gallium nitride (InAlGaN), or the like. In addition, the buffer layer may be made of III-V group compound semiconductor other than the gallium nitride. For example, when the substrate 10 is a sapphire substrate 10, it is important to grow the buffer layer so as to prevent a mismatch due to a difference of a lattice constant and a thermal expansion coefficient between the substrate and the nitride semiconductor layer 30 including the gallium nitride.

Referring to FIG. 1, the 2-dimensional electron gas (2DEG) channel 35 is disposed in the nitride semiconductor layer 30. For example, when a bias voltage is applied to the gate electrode 70, electrons move through the 2DEG channel 35 in the nitride semiconductor layer 30 and current flows between a drain electrode 50 and a source electrode 60. As nitride forming the nitride semiconductor layer 30, the gallium nitride (GaN), the aluminum gallium nitride (AlGaN), the indium nitride gallium (InGaN), the indium aluminum gallium nitride (InAlGaN), or the like, are used.

According to the exemplary embodiment of the present invention, the nitride semiconductor layer 30 is a heterojunctioned gallium nitride based semiconductor layer 30. The 2-dimensional electron gas channel 35 is formed due to an energy bandgap difference at a heterojunctioned interface surface. In the heterojunctioned gallium nitride based semiconductor layer 30, the smaller the difference in the lattice constant between the heterojunctions, the smaller the difference in the bandgap and polarity becomes, such that the formation of the 2DEG channel 35 is suppressed. Free electrons move from a material having a large bandgap to a material having a small bandgap due to discontinuity of the energy bandgap at the time of the heterojunction. These electrons may be accumulated at the heterojunctioned interface surface to form the 2DEG channel 35 and current may flow between the drain electrode 50 and the source electrode 60.

Another exemplary embodiment of the present invention will be described. Referring to FIG. 1, the nitride semiconductor layer 30 includes a first nitride layer and a second nitride layer 33. The first nitride layer 31 is disposed on the substrate 10 and includes a gallium nitride based material. The second nitride layer 33 is heterojunctioned to the first nitride layer 31 and includes a heterogeneous gallium nitride based material having a larger energy bandgap than the first nitride layer 31. In this case, the second nitride layer 33 serves to supply electrons to the 2DEG channel 35 disposed in the first nitride layer 31. As one example, the second nitride layer 33 providing electrons may be formed to have a thinner thickness than that of the first nitride layer 31.

According to another exemplary embodiment of the present invention, the first nitride layer 31 may include the gallium nitride (GaN) and the second nitride layer 33 may include any one of the aluminum gallium nitride (AlGaN), the indium nitride gallium (InGaN), and the indium aluminum gallium nitride (InAlGaN). According to the exemplary embodiment of the present invention, the first nitride layer 31 includes the gallium nitride (GaN) and the second nitride layer 33 includes the aluminum gallium nitride (AlGaN).

In addition, the exemplary embodiment of the present invention will be described with reference to FIG. 1. In the exemplary embodiment of the present invention, the second nitride layer 33 is configured to include a first area 33a in which the D-mode FET is disposed and a second area 33b in which a Schottky diode 200 is disposed. In this case, the first area and the second area are separated from each other and the 2DEG channel is not formed in the vicinity of the surface of the first nitride layer 31 between the first area and the second area.

Describing another exemplary embodiment of the present invention with reference to FIG. 1, the 2DEG channel is not disposed between the D-mode FET and the Schottky diode part.

In addition, describing another exemplary embodiment of the present invention with reference to FIG. 1, in the D-mode FET, the source electrode 60 and the drain electrode 50 ohmic-contacts with the nitride semiconductor layer 30.

In addition, according to another exemplary embodiment of the present invention, in the Schottky diode part, a cathode electrode 90 ohmic-contacts with the nitride semiconductor layer 30.

Another exemplary embodiment of the present invention will be described with reference to FIGS. 1 and 2.

According to the exemplary embodiment of the present invention, the source electrode 60 of the D-mode FET ohmic-contacts with the first nitride layer 31 that is exposed by etching the second nitride layer 33. The drain electrode 50 of the D-mode FET ohmic-contacts with the first nitride layer 31 that is exposed by etching the second nitride layer 33. Further, the gate electrode 70 of the D-mode FET Schottky-contacts the second nitride layer 33 between the source electrode 60 and the drain electrode 50.

Further, a dielectric layer 40 insulating between the source electrode 60 and the drain electrode 50 of the D-mode FET and the Schottky diode part is disposed.

In addition, referring to FIG. 1, the dielectric layer 40 is disposed on the second nitride layer 33 between the source electrode 60 and the drain electrode 50 and on the gate electrode 70. In addition, in the Schottky diode part, the dielectric layer 40 is disposed between the cathode electrode 90 and the anode electrode 80.

According to another exemplary embodiment of the present invention, as shown in FIG. 1, the source electrode 60 and the drain electrode 50 are each ohmic-contacted over each portion of the first nitride layer 31 and the second nitride layer 33.

Referring to FIG. 2, in order to form the channel over the wide area, the source electrode 60 and the drain electrode 50 has a rugged structure in which grooves and projections are formed on a plane and has an engaged shape to be spaced apart from each other at a predetermined distance.

Next, another exemplary embodiment of the present invention will be described with reference to FIG. 4.

According to another exemplary embodiment of the present invention, the nitride semiconductor device further includes an E-mode FET 300. The E-mode FET 300 includes electrodes on the nitride semiconductor layer 30 to form a normally-off operating enhancement-mode (E-mode) HEMT structure. The E-mode FET 300 has the drain electrode connected to the source electrode 60 of the D-mode FET 100 so as to be cascode-connected to the D-mode FET 100.

In this case, a gate terminal of the D-mode FET 100 is connected to the anode terminal of the Schottky diode and the drain terminal of the low pressure resistance, high current type enhancement-mode (E-mode) FET is connected to the source terminal of the D-mode FET 100 to form the improved high power E-mode FET.

The E-mode FET structure may use the technology well-known in the art and may also use the technology of forming the E-mode FET by Schottky-contacting with the source electrode disclosed in Korean Patent Application Nos. 10-2011-0038611, 10-2011-0038612, 10-2011-0038613, 10-2011-0038614, and 10-2011-0038615 that have been already filed in Korea by the present applicant, all of which are incorporated in the description of the E-mode FET structure of the present invention.

The E-mode FET 300 may be manufactured on the same substrate together with the D-mode FET 100 and may use the high current type FET using silicon, or the like.

The nitride semiconductor device used for the exemplary embodiment of the present invention may be configured by a combination of a high current, high pressure resistance type D-mode FET, a constant voltage supply Schottky diode, and a high current, a low pressure resistance type E-mode FET.

Next, another exemplary embodiment of the present invention will be described with reference to FIG. 5.

According to another exemplary embodiment of the present invention, a Schottky diode part 200 is configured to include two Schottky diodes 201 and 202 that are connected to each other in series. FIG. 5 shows the nitride semiconductor device or the power device that includes the E-mode FET 300.

In addition, a semiconductor power device according to another exemplary embodiment of the present invention will be described. FIGS. 1 to 5 may also be applied to the semiconductor power device according to the exemplary embodiment of the present invention.

Describing the exemplary embodiment of the present invention with reference to FIGS. 4 and 5, the nitride semiconductor power device is configured to include the D-mode FET 100, the E-mode FET 300, and the Schottky diode part 200. Hereinafter, an exemplary embodiment of the present invention will be described with reference to the exemplary embodiment of the nitride semiconductor device as described above.

The D-mode FET 100 is configured to dispose electrodes on the nitride semiconductor layer 30 forming the 2-dimensional electron gas (2DEG) channel 35. The D-mode FET 100 forms the normally-on operating depletion-mode (D-mode) HEMT structure.

The E-mode FET 300 forms a normally-off operating enhancement-mode (E-mode) HEMT structure. The E-mode FET 300 has the drain electrode connected to the source electrode 60 of the D-mode FET 100 so as to be cascode-connected to the D mode FET 100. Further, the source electrode is connected to a ground.

The Schottky diode part 200 includes the anode electrode 80 that Schottky-contacts the nitride semiconductor layer 30 and the cathode electrode connected to the ground, wherein the anode electrode 80 is connected to the gate electrode of the D-mode FET 100. The Schottky diode part 200 increases the gate driving voltage of the D-mode FET 100 by a threshold voltage Vth.

According to the exemplary embodiment of the present invention, referring to FIG. 5, two Schottky diodes 201 and 202 are connected to each other in series.

Next, a method for manufacturing a nitride semiconductor device according to another exemplary embodiment of the present invention will be described in detail.

FIGS. 6A-6D are diagrams schematically showing a method for manufacturing a nitride semiconductor device according to an exemplary embodiment of the present invention. FIGS. 6A-6D and FIGS. 1 to 5 showing the above-mentioned nitride semiconductor device will be referred in the description of the exemplary embodiments of the present invention.

The method for manufacturing a nitride semiconductor device according to the exemplary embodiment of the present invention is configured to include forming the nitride semiconductor layer, forming the D-mode FET structure, forming the Schottky diode structure, and connecting the electrodes.

FIGS. 6A and 6B show a process of forming the nitride semiconductor layer 30 that is disposed on the substrate 10 and has the 2-dimensional electron gas (2DEG) channel 35 formed therein.

First, referring to FIG. 6A, the nitride semiconductor layer 30 that has the 2-dimensional electron gas (2DEG) channel formed therein is disposed on the top of the substrate 10. The substrate 10 may be manufactured using at least any one of silicon (Si), silicon carbide (SiC) and sapphire (Al₂O₃). As nitride forming the nitride semiconductor layer 30, the gallium nitride (GaN), the aluminum gallium nitride (AlGaN), the indium nitride gallium (InGaN), the indium aluminum gallium nitride (InAlGaN), or the like, are used.

The nitride semiconductor layer 30 may be formed by epitaxially growing the nitride single crystal thin film. The nitride semiconductor layer 30 is controlled to be selectively grown at the time of the epitaxial growth, thereby preventing the overgrowth thereof. If the nitride semiconductor layer 30 overgrows, a process of planarizing the nitride semiconductor layer 30 using an etch back process or a chemical mechanical polishing process may be further provided.

According to a method for manufacturing a nitride semiconductor device of another exemplary embodiment of the present invention, the first nitride layer 31 and the second nitride layer 33 shown in FIG. 6A are formed by the epitaxial growth process. First, the first nitride layer 31 is formed over the substrate 10 by epitaxially growing the gallium nitride based single crystal thin film. According to another exemplary embodiment of the present invention, the first nitride layer 31 is formed by epitaxially growing the gallium nitride (GaN). Next, the second nitride layer 33 is formed by epitaxially growing the nitride layer including a heterogeneous gallium nitride based material having a larger energy bandgap than the first nitride layer 31 using the first nitride layer 31 as a seed layer. According to another exemplary embodiment of the present invention, the second nitride layer 33 is formed by epitaxially growing the gallium nitride based single crystal including any one of the aluminum gallium nitride (AlGaN), the indium nitride gallium (InGaN), and the indium aluminum gallium nitride (InAlGaN). The second nitride layer 33 is formed by epitaxially growing the aluminum gallium nitride (AlGaN). As one example, the second nitride layer 33 providing electrons may be formed to have a thinner thickness than that of the first nitride layer 31.

An example of the epitaxial growth process for forming the first and second nitride layers 31 and 33 may include liquid phase epitaxy (LPE), chemical vapor deposition (CVD), molecular beam epitaxy (MBE), metalorganic CVD (MOCVD), or the like.

Although not shown, another exemplary embodiment of the present invention may further include forming the buffer layer on the substrate 10, prior to forming the nitride semiconductor layer 30 on the top of the substrate 10. The buffer layer (not shown) is provided to solve problems due to the lattice mismatch between the substrate 10 and the nitride semiconductor layer 30.

According to another exemplary embodiment of the present invention, the forming of the nitride semiconductor layer includes forming the first nitride layer 31 over the substrate 10 by epitaxial growth process wherein the first nitride layer 31 includes the gallium nitride based material and forming the second nitride layer 33 using the first nitride layer 31 as a seed layer by epitaxial growth process wherein the second nitride layer 33 includes the heterogeneous gallium nitride based material having a larger energy bandgap than the first nitride layer 31.

Referring to FIG. 6B, according to another exemplary embodiment of the present invention, the forming of the nitride semiconductor layer further includes separating the first area 33a from the second area 33b and exposing the first nitride layer 31 by etching a portion of the second nitride layer 33.

Next, FIG. 6C shows forming the D-mode FET structure and forming the Schottky diode structure.

At the forming of the D-mode FET (100) structure, the normally-on operating D-mode FET (100) structure is formed by forming the source and drain electrodes 60 and 50 that ohmic-contact with the nitride semiconductor layer 30 and the gate electrode 70 Schottky-contacts the nitride semiconductor layer 30.

The source electrode 60, the drain electrode 50, and the gate electrode 70 may be formed as a metal electrode using at least one metal of aluminum (Al), molybdenum (Mo), gold (Au), nickel (Ni), platinum (Pt), titanium (Ti), palladium (Pd), iridium (Ir), rhodium (Rh), cobalt (Co), tungsten (W), tantalum (Ta), copper (Cu), and zinc (Zn), metal silicide, and an alloy thereof. The gate electrode 70 may use metals different from the drain electrode 50 or/and the source electrode 60.

In addition, describing the exemplary embodiment of the present invention with reference to FIG. 1, at the forming of the D-mode FET structure, the source electrode 60 and the drain electrode 50 are formed on the exposed first nitride layer 31 while being ohmic-contacted thereto and the gate electrode 70 is formed on the first area 33a between the source electrode 60 and the drain electrode 50 while being Schottky-contacted thereto. In this configuration, as shown in FIG. 1, a portion of the source electrode 60 and the drain electrode 50 may be formed so as to cover a portion of the first area 33a of the second nitride layer 33 and may be formed so as not to cover a portion of the first area 33a of the second nitride layer 33, unlike the case shown.

Describing the exemplary embodiment of the present invention with reference to FIG. 1, the source electrode 60 and the drain electrode 50 are each formed so as to be ohmic-contacted over each portion of the first nitride layer 31 and the first area 33a.

Next, the forming of the Schottky diode structure 200 shown in FIG. 6C will be described below. At the forming of the Schottky diode structure 200, the Schottky diode structure including the cathode electrode 90 ohmic-contacting with the nitride semiconductor layer 30 and the anode electrode 80 Schottky-contacting with the nitride semiconductor layer 30 is formed so as to be separated from the D-mode FET 100 structure.

The anode electrode 80 and the cathode electrode 90 may be formed as a metal electrode using at least one metal of aluminum (Al), molybdenum (Mo), gold (Au), nickel (Ni), platinum (Pt), titanium (Ti), palladium (Pd), iridium (Ir), rhodium (Rh), cobalt (Co), tungsten (W), tantalum (Ta), copper (Cu), and zinc (Zn), metal silicide, and an alloy thereof. The anode electrode and the cathode electrode 90 may made of metals different from each other.

At the forming of the D-mode FET structure shown in FIG. 6C and the forming of the Schottky diode structure, an inter-device interference is minimized by the etching of a channel forming layer, for example, the second nitride layer 33 between the D-mode 100 and the Schottky diode part 200 and by an inter-device isolation through the formation of an insulating layer, i.e., the dielectric layer 40 therebetween.

In addition, further describing the exemplary embodiment of the present invention with reference to FIG. 6D, at the forming of the Schottky diode structure 200, the cathode electrode 90 and the anode electrode 80 are formed on the second area 33b. Further, the dielectric layer 40 is formed between the source electrode 60 and the drain electrode 50 of the D-mode FET 100 and the Schottky diode structure, on the second area 33b between the cathode electrode 90 and the anode electrode 80 of the Schottky diode 200, and on the first area 33a between the source electrode 60 and the drain electrode 50 of the D-mode FET 100 and the gate electrode 70.

The dielectric layer 40 may be configured of an oxide layer. According to the exemplary embodiment of the present invention, the dielectric layer 40 may be made of at least one of SiN, SiO₂, and Al₂O₃.

Continuously, the exemplary embodiment of the method for manufacturing a nitride semiconductor device will be described. At the electrode connection process (not shown), in order to increase the gate driving voltage of the D-mode FET 100, the gate electrode 70 of the D-mode FET 100 is connected to the anode electrode 80 of the Schottky diode 200.

In the exemplary embodiment of the present invention, after the dielectric layer 40 shown in FIG. 6D is formed, the gate electrode 70 of the D-mode FET 100 is connected to the anode electrode 80 of the Schottky diode 200.

In addition, another exemplary embodiment of the present invention will be described with reference to FIGS. 4 and/or 5.

The method for manufacturing a nitride semiconductor device according to the exemplary embodiment of the present invention further includes forming the E-mode FET 300 structure and cascode-connecting the E-mode FET 300 to the D-mode FET 100.

At the E-mode FET 300 structure, the source electrode, the drain electrode, and the gate electrode are formed on the nitride semiconductor layer to form the normally-off operating E-mode FET structure. The technologies of forming the E-mode FET structure are well-known in the art and also disclosed in Patent Application Nos. 10-2011-0038611, 10-2011-0038612, 10-2011-0038613, 10-2011-0038614, and 10-2011-0038615 that are already filed in Korea by the present applicant. Korean Patent Application Nos. 10-2011-0038611, 10-2011-0038612, 10-2011-0038613, 10-2011-0038614, and 10-2011-0038615 disclose the E-mode FET formed by Schottky-contacting the source electrode, all of which are incorporated in the description of forming the E-mode FET structure of the present invention.

At the cascode-connecting of the FET 300 to the D-mode FET 100, the drain electrode of the E-mode FET 300 is connected to the source electrode of the D-mode FET 100.

In addition, describing the method for manufacturing a nitride semiconductor device according to another exemplary embodiment of the present invention with reference to FIG. 5, at the forming of the Schottky diode structure 200, two Schottky diodes 201 and 202 are formed to be connected in series.

As set forth above, the exemplary embodiment of the present invention can implement the normally-off (or enhanced mode) by simultaneously manufacturing the normally-on GaN HEMT and the diode on the same substrate and cascode-connecting the normally-on GaN HEMT with the normally-off FET and increase the Vgs of the normally-on GaN HEMT in the integrated type without the additional external circuits, thereby reducing the loss of the device and implementing the high electrical characteristics and efficiency.

In addition, the exemplary embodiment of the present invention can increase the driving voltage of the gate terminal of the D-mode FET to increase the electrical characteristics and efficiency as compared with the related art, integrate the normally-on GaN HEMT, the diode, and the normally-off FET on the same substrate to save costs and to be appropriately used for the large-power switching circuit configuration.

It is obvious that various effects directly stated according to various exemplary embodiment of the present invention may be derived by those skilled in the art from various configurations according to the exemplary embodiments of the present invention.

The accompanying drawings and the above-mentioned exemplary embodiments have been illustratively provided in order to assist in understanding of those skilled in the art to which the present invention pertains. Therefore, various exemplary embodiments of the present invention may be implemented in modified forms without departing from an essential feature of the present invention. In addition, a scope of the present invention should be interpreted according to claims and includes various modifications, alterations, and equivalences made by those skilled in the art.

What is claimed is:

1. A nitride semiconductor device, comprising:
a nitride semiconductor layer over a substrate wherein the nitride semiconductor layer has a two-dimensional electron gas (2DEG) channel formed therein;
a D-mode FET that includes a gate electrode Schottky-contacting with the nitride semiconductor layer to form a normally-on operating depletion-mode (D-mode) HEMT structure; and
a Schottky diode part that includes an anode electrode Schottky-contacting with the nitride semiconductor layer and increases a gate driving voltage of the D-mode FET, the anode electrode being connected to the gate electrode of the D-mode FET.

2. The nitride semiconductor device according to claim 1, wherein the 2DEG channel is not formed between the D-mode FET and the Schottky diode part.

3. The nitride semiconductor device according to claim 1, wherein a source electrode and a drain electrode of the D-mode FET ohmic-contact with the nitride semiconductor layer.

4. The nitride semiconductor device according to claim 1, wherein a cathode electrode of the Schottky diode part ohmic-contacts with the nitride semiconductor layer.

5. The nitride semiconductor device according to claim 1, wherein the nitride semiconductor layer includes:
a first nitride layer over the substrate wherein the first nitride layer includes a gallium nitride material; and
a second nitride layer heterojunctioned to the first nitride layer wherein the second nitride layer includes a heterogeneous gallium nitride based material with a larger energy bandgap than the first nitride layer.

6. The nitride semiconductor device according to claim 5, wherein the first nitride layer includes gallium nitride (GaN), and
the second nitride layer includes any one of aluminum gallium nitride (AlGaN), indium gallium nitride (InGaN), and indium aluminum gallium nitride (InAlGaN).

7. The nitride semiconductor device according to claim 5, wherein the second nitride layer includes a first area in which the D-mode FET is disposed and a second area in which the Schottky diode part is disposed, the first area and the second area are separated from each other, and the 2DEG channel is not formed in the vicinity of a surface of the first nitride layer between the first area and the second area.

8. The nitride semiconductor device according to claim 5, wherein the D-mode FET includes:
a source electrode ohmic-contacting with the first nitride layer exposed by etching the second nitride layer;
a drain electrode ohmic-contacting with the first nitride layer exposed by etching the second nitride layer; and
a gate electrode Schottky-contacting with the second nitride layer between the source electrode and the drain electrode, and
a dielectric layer insulating between the Schottky diode part and the source and drain electrodes is provided.

9. The nitride semiconductor device according to claim 8, wherein the source electrode and the drain electrode are each ohmic-contacted over each portion of the first nitride layer and the second nitride layer.

10. The nitride semiconductor device according to claim 1, further comprising an E-mode FET that includes electrodes formed on the nitride semiconductor layer to form a normally-off operating enhancement-mode (E-mode) HEMT structure and has a drain electrode connected to the source electrode of the D-mode FET so as to be cascode-connected to the D-mode FET.

11. The nitride semiconductor device according to claim 1, wherein the Schottky diode part is formed so that two Schottky diodes are connected to each other in series.

12. The nitride semiconductor device according to claim 10, wherein the Schottky diode part is formed so that two Schottky diodes are connected to each other in series.

13. A nitride semiconductor power device, comprising:
a D-mode FET that includes electrodes formed on a nitride semiconductor layer forming a 2-dimensional electron gas (2DEG) channel to form a normally-on operating depletion mode (D-mode) HEMT structure;
an E-mode FET that forms a normally-off operating enhancement-mode (E-mode) HEMT structure and has a source electrode connected to a ground and a drain electrode connected to a source electrode of the D-mode FET so as to be cascode-connected to the D-mode FET; and
a Schottky diode part that includes an anode electrode Schottky-contacting with the nitride semiconductor layer and a cathode electrode connected to the ground and increases a gate driving voltage of the D-mode FET, the anode electrode being connected to a gate electrode of the D-mode FET.

14. The nitride semiconductor power device according to claim 13, wherein the Schottky diode part is formed so that two Schottky diodes are connected to each other in series.

15. A method for manufacturing a nitride semiconductor device, comprising:
forming a nitride semiconductor layer over a substrate wherein the nitride semiconductor layer has a two-dimensional electron gas (2DEG) channel formed therein;
forming a normally-on operating D-mode FET structure by forming source and drain electrodes ohmic-contacting with the nitride semiconductor layer and a gate electrode Schottky-contacting with the nitride semiconductor layer;
forming a Schottky diode structure that includes a cathode electrode ohmic-contacting with the nitride semiconductor layer and an anode electrode Schottky-contacting with the nitride semiconductor layer, the Schottky diode structure being separated from the D-mode FET structure; and
connecting the gate electrode of the D-mode FET to the anode electrode of the Schottky diode part so that a gate driving voltage of the D-mode FET is increased by the Schottky diode.

16. The method according to claim 15, wherein the forming of the nitride semiconductor layer includes:
forming a first nitride layer over the substrate by epitaxial growth process, wherein the first nitride layer includes a gallium nitride based material; and
forming a second nitride layer by epitaxial growth process using the first nitride layer as a seed layer, wherein the second nitride layer includes a heterogeneous gallium nitride based material having a larger energy bandgap than the first nitride layer.

17. The method according to claim 16, wherein the forming of the nitride semiconductor layer further comprises exposing the first nitride layer by etching a portion of the second nitride layer, so that the second nitride layer is separated into the first area and the second area,
wherein at the forming of the D-mode FET structure, the source electrode and the drain electrode are formed on the exposed first nitride layer while being ohmic-contacted thereto and the gate electrode is formed on the first area between the source electrode and the drain electrode while being Schottky-contacted thereto,
at the forming of the Schottky diode structure, the cathode and anode electrodes are formed on the second area,
a dielectric layer is formed between the Schottky diode structure and the source and drain electrodes, on the second area between the cathode electrode and the anode electrode, and over the gate electrode and the first area between the source electrode and the drain electrode, and
after the dielectric layer is formed, the gate electrode of the D-mode FET is connected to the anode electrode of the Schottky diode part.

18. The method according to claim 17, wherein the source electrode and the drain electrode are each formed so as to be ohmic-contacted over each portion of the first nitride layer and the first area.

19. The method according to claim 15, further comprising:
forming the source electrode, the drain electrode, and the gate electrode on the nitride semiconductor layer to form the normally-off operating E-mode FET structure; and
connecting the drain electrode of the E-mode FET to the source electrode of the D-mode FET to cascode-connect the E-mode FET to the D-mode FET.

20. The method according to claim 15, wherein at the forming of the Schottky diode structure, two Schottky diodes are formed so as to be connected to each other in series.

21. The method according to claim 19, wherein at the forming of the Schottky diode structure, two Schottky diodes are formed so as to be connected to each other in series.
